(19) United States
(12) Patent Application Publication
(10) Pub. No.: US 2006/0125048 A1
(43) Pub. Date: Jun. 15, 2006

(54) Integrated semiconductor device and method of manufacturing the same

(75) Inventor: Hiroshi Miki, Tokyo (JP)

Correspondence Address: Stanley P. Fisher;Reed Smith LLP, Suite 1400, 3110 Fairview Park Drive, Falls Church, VA, 22042-4503, US

(73) Assignee: Hitachi, Ltd.

(21) Appl. No.: 11/196,421

(22) Filed: Aug. 4, 2005

(30) Foreign Application Priority Data
Dec. 13, 2004 (JP) 2004-359724

(51) Int. Cl. H01L 29/00

(52) U.S. Cl. 257/532

(57) ABSTRACT

An integrated semiconductor device comprising an analog integrated circuit or mixed signal integrated circuit having a capacitor, wherein the dielectric film of the capacitor is a laminated film consisting of a first dielectric film essentially composed of aluminum oxide and a second dielectric film essentially composed of crystallized niobium oxide. This integrated semiconductor device is small in size and has a low temperature coefficient and high reliability. The niobium oxide is crystallized to increase its dielectric constant and reduce its loss. To reduce the temperature coefficient, the film thickness ratio of the aluminum oxide layer to the niobium oxide layer is set to 0.2 to 1, preferably 0.4 to 0.7.

### CLAIM OF PRIORITY

The present application claims priority from Japanese application JP 2004-359724 filed on Dec. 13, 2004, the content of which is hereby incorporated by reference into this application.

### FIELD OF THE INVENTION

The present invention relates to an integrated semiconductor device and to a method of manufacturing the same and, particularly, to an integrated semiconductor device which can be reduced in size, experiences small changes in its characteristic properties caused by ambient temperature and operation conditions and has a highly reliable capacitor and to a method of manufacturing the same.

### BACKGROUND OF THE INVENTION

In an integrated circuit for carrying out the analog processing of an electric signal, the values of a passive device such as capacitor, resistor or inductor are important factors for determining circuit operation, in addition to the characteristic properties of an active device typified by MOSFET. Heretofore, most of these passive devices have been external to a printed circuit board. To meet demand for the higher operation speed of an integrated circuit and the lower costs thereof by reducing the number of parts, attempts are being made energetically to manufacture an on-chip device by forming the above passive device on a semiconductor chip. Since the inductance of wiring from the chip to a capacitor in particular becomes a great obstacle to circuit operation in the conventional external attachment system, needs for an on-chip capacitor are high.

This on-chip capacitor has technical targets to be attained, such as reductions in parasitic electrode capacitance and size and the minimum additional process cost to meet customers' demand for higher speed and lower costs. To attain these targets, there is proposed technology for forming a capacitor in the wiring step after the process of a active device is completed. Since metal wiring is used as the electrodes of a capacitor in this technology, this capacitor is called “MIM (Metal-Insulator-Metal) capacitor” (for example, refer to JP-A No. 53408/1994, JP-A No. 320026/2001 and JP-A No. 164506/2002).

This MIM technology will be described with reference to FIG. 2. A first wiring layer (102) is existent on a semiconductor substrate (101) having an active device formed thereon and consists of a metal layer (104) essentially composed of aluminum and upper and lower layers (103, 105) made of titanium nitride as a barrier metal. A second wiring layer (106) is existent above the first wiring layer and consists of a metal layer (108) essentially composed of aluminum and upper and lower layers (107, 109) made of a barrier metal. An ordinary interlayer dielectric (110) is interposed between the two metal wiring layers, and an opening is formed in the interlayer dielectric in a portion which will become an MIM capacitor. A silicon nitride film (111) is formed on the inner wall of the opening as a capacitor dielectric. This capacitor dielectric and tungsten (112) as a top electrode are buried in the opening.

However, this MIM capacitor has technical limitation mainly in the respect of downsizing. To reduce the size of the capacitor, the capacitor dielectric must be made thin. However, the thickness can be reduced down to several tens of nm. To form the capacitor dielectric in the opening shown in FIG. 2, the thickness of the film becomes non-uniform in accordance with a level difference in the opening. In order to form a silicon nitride film while the requirement for the heat resistance of the first wiring layer (102) is satisfied, low-temperature CVD making use of plasma must be employed because step coverage becomes lower than that of ordinary thermal CVD. Therefore, the capacity per unit area of the capacitor when a silicon nitride film is used is 1 fF/μM² to 2 fF/μm². This determines the limit of the density of capacitance of the conventional MIM capacitor composed of a silicon nitride film, therefore, limitation to the downsizing of the capacitor.

To cope with this, there is proposed technology for further reducing the size of a capacitor by using a dielectric having a higher dielectric constant. Aluminum oxide (dielectric constant of about 8), hafnium oxide and tantalum oxide (both having a dielectric constant of 20 to 30) are mainly studied as high-dielectric materials. The latter two materials have a dielectric constant 3 to 4 times higher than that of a silicon nitride film (dielectric constant of about 7). This makes it possible to increase the capacitance, and it is known that a dielectric thin film having excellent step coverage can be formed at a temperature of about 400° C. or lower which does not cause any problem with the heat resistance of wiring layers by employing atomic-layer deposition (ALD) for aluminum oxide and hafnium oxide in particular (refer to IEEE Transactions on Electron Devices, vol. 51, pp. 886-894, for example).

### SUMMARY OF THE INVENTION

The first problem to be solved is that a dielectric material having a high dielectric constant is liable to become defective and inferior in reliability as a capacitor. The second problem is that a material having a high dielectric constant has great changes in dielectric constant caused by temperature variations, whereby its capacitance is changed by variations in ambient temperature and operation conditions with the result of fluctuations in circuit operation. Further, the third problem is that the above two problems conflict with each other. That is, when the number of defects is reduced to improve reliability, temperature variations become large and when temperature variations are reduced, reliability lowers. Particularly, the third problem has been first discovered by experimental studies conducted by the inventors of the present invention.

To solve the above problems, niobium oxide and aluminum oxide layers are laminated together as the dielectric film of a capacitor in the present invention. Particularly, the density of defects is reduced by crystallizing niobium oxide. To reduce the temperature coefficient in particular, the optimal value of the thickness ratio of the aluminum oxide film to the niobium oxide film is used.

The first effect of the present invention is that the number of defects is reduced by crystallizing niobium oxide to improve reliability. The dielectric loss of niobium oxide which is closely related with defects is generally several % or more when niobium oxide is amorphous and can be reduced to less than 1% when niobium oxide is crystallized. As an effect incidental to the above effect, the dielectric constant of niobium oxide is increased from about 20 in an amorphous state to about 50 by crystallization, thereby improving the density of capacitance. In the case of tantalum oxide of the prior art, since a temperature required for crystallization is about 700° C., tantalum oxide could not be crystallized at a temperature within the heat resistance temperature range of metal wiring. In the case of hafnium oxide, part of hafnium oxide was crystallized but its dielectric loss could not be fully reduced and also its reliability could not be improved.

Another effect of the present invention is that the temperature coefficient of capacitance can be made small. Therefore, in the present invention, an aluminum oxide layer and a crystallized niobium oxide layer are laminated together. This effect is as follows. That is, although the defect density of the above niobium oxide is reduced by crystallization, thereby improving its reliability and dielectric constant, its temperature coefficient becomes a large negative value at about −600 ppm/° C. This temperature coefficient is greatly outside a range of ±100 ppm/° C. which is required for stable circuit operation and not practical. Aluminum oxide is formed in an suitable film thickness ratio as a material having a positive temperature coefficient to correct temperature characteristics so as to suppress the temperature coefficient.

By employing these two materials, a capacitor having a large capacitance, high reliability and a small temperature coefficient can be realized.

### BRIEF DESCRIPTION OF THE DRAWINGS

FIG. 1 is a sectional view of the capacitor of the present invention;

FIG. 2 is a sectional view of a capacitor of the prior art;

FIG. 3A is a diagram showing the method of manufacturing a capacitor of the present invention (Embodiment 1);

FIG. 3B is a diagram showing the method of manufacturing a capacitor of the present invention (Embodiment 1);

FIG. 3C is a diagram showing the method of manufacturing a capacitor of the present invention (Embodiment 1);

FIG. 3D is a diagram showing the method of manufacturing a capacitor of the present invention (Embodiment 1);

FIG. 3E is a diagram showing the method of manufacturing a capacitor of the present invention (Embodiment 1);

FIG. 3F is a diagram showing the method of manufacturing a capacitor of the present invention (Embodiment 1);

FIG. 3G is a diagram showing the method of manufacturing a capacitor of the present invention (Embodiment 1);

FIG. 4 is a diagram showing the electric characteristics of the capacitor of the present invention (Embodiment 1);

FIG. 5 is a diagram showing the electric characteristics of the capacitor of the present invention (Embodiment 1);

FIG. 6 is a diagram showing the electric characteristics of the capacitor of the present invention (Embodiment 1);

FIG. 7 is a diagram showing the electric characteristics of the capacitor of the present invention (Embodiment 1);

FIG. 8 is a diagram showing the electric characteristics of the capacitor of the present invention (Embodiment 1);

FIG. 9 is a diagram showing the electric characteristics of the capacitor of the present invention (Embodiment 1);

FIG. 10 is a sectional view of the capacitor of the present invention (Embodiment 1);

FIG. 11 is a sectional view of the capacitor of the present invention (Embodiment 2);

FIG. 12 is a sectional view of the capacitor of the present invention (Embodiment 2);

FIG. 13 is a sectional view of the capacitor of the present invention (Embodiment 3);

FIG. 14 is a sectional view of the capacitor of the present invention (Embodiment 4); and

FIG. 15 shows an example when the capacitor of the present invention is used in a GSM radio communication apparatus.

### DETAILED DESCRIPTION OF THE PREFERRED EMBODIMENTS

Preferred embodiments of the present invention will be described hereinbelow with reference to the accompanying drawings.

### Embodiment 1

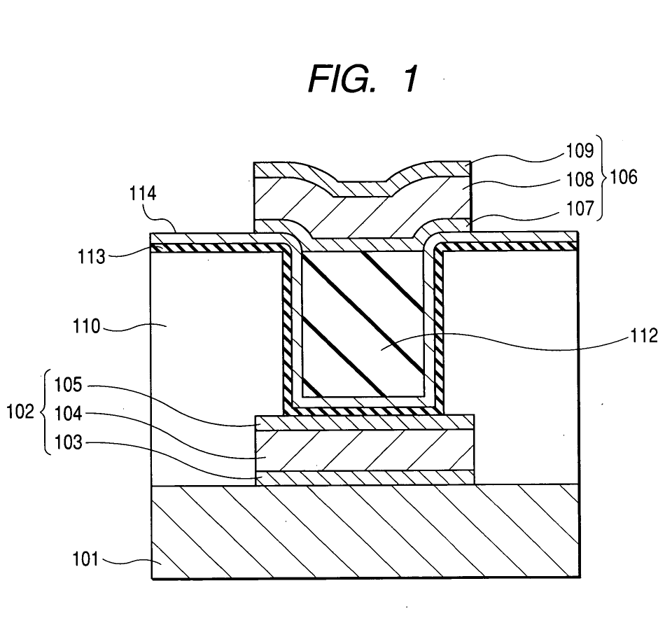

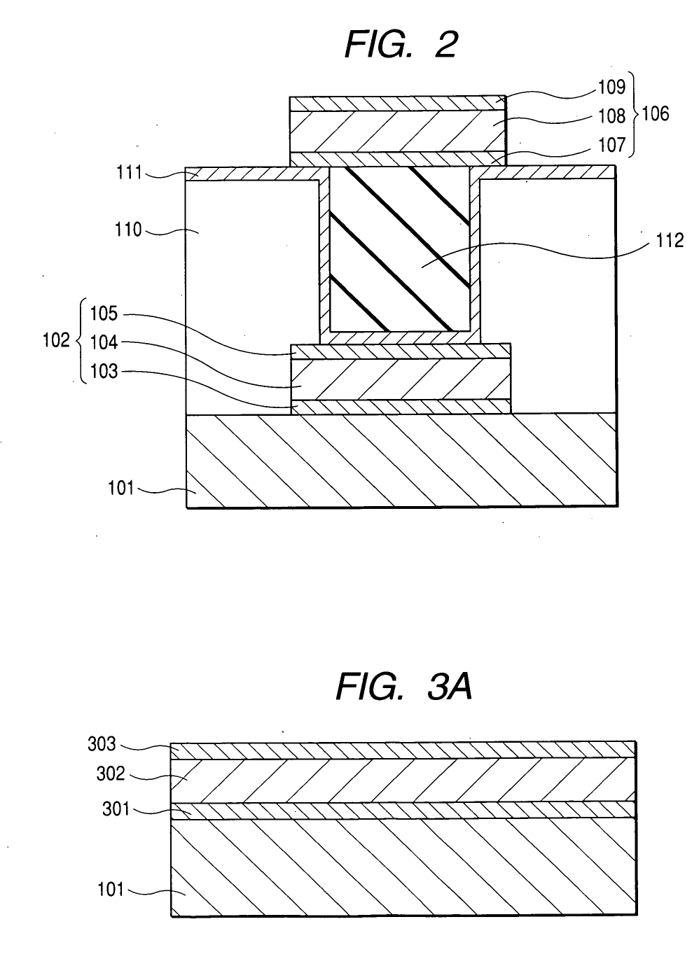

FIG. 1 is a sectional view of Embodiment 1 of the present invention. A first wiring layer (102) is existent on a semiconductor substrate (101) having an active device formed thereon and consists of a metal layer (104) and upper and lower layers (103, 105) made of titanium nitride as a barrier metal. A second wiring layer (106) is existent above the first wiring layer and consists of a metal layer (108) and upper and lower layers (107, 109) made of a barrier metal. An ordinary interlayer dielectric (110) is interposed between the two metal wiring layers, and an opening is formed in the interlayer dielectric in a portion which will become an MIM capacitor. An aluminum oxide layer (113) and a niobium oxide layer (114) are formed as capacitor dielectrics on the inner wall of the opening. The aluminum oxide layer (113) is an amorphous film having a thickness of 2 nm and the niobium oxide layer is a crystallized film having a thickness of 5 nm. The opening is filled with these capacitor dielectrics and tungsten (112) as a top electrode.

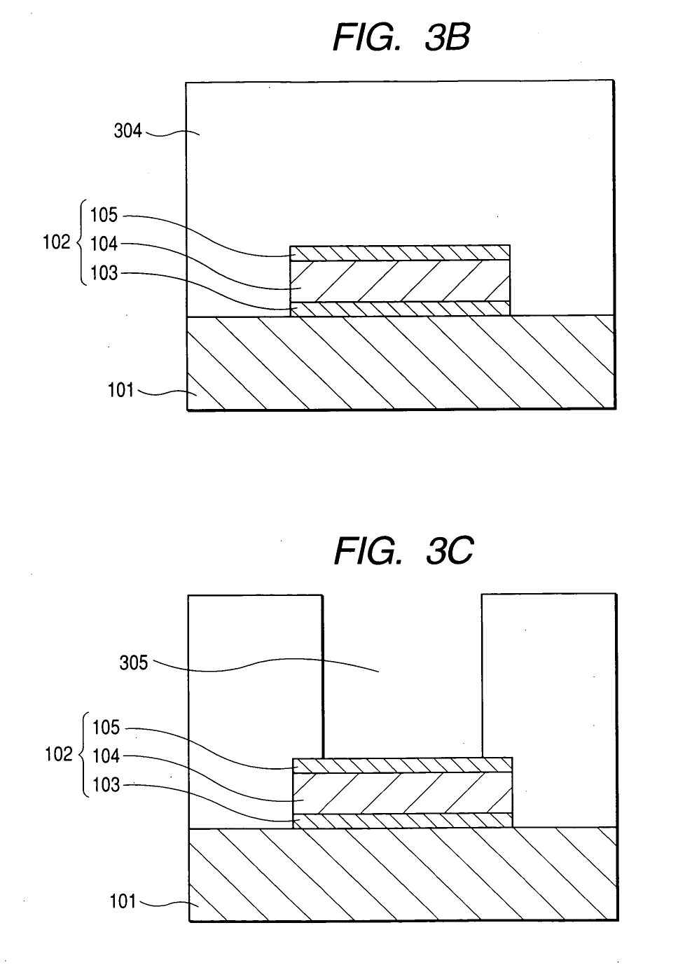

A detailed description is subsequently given of the method of manufacturing the structure of FIG. 1 with reference to FIGS. 3A to 3G. A barrier metal thin film (301), wiring metal thin film (302) and barrier metal thin film (303) are formed sequentially on a semiconductor substrate (101) including an active device manufactured by a known method to obtain the structure shown in FIG. 3A. The top barrier metal thin film (303) in particular is made of titanium nitride. These thin films are processed by photolithography and dry etching to form the first wiring layer (102), and an interlayer dielectric (304) essentially composed of SiO₂ is deposited to obtain the structure shown in FIG. 3B. Further, an opening (305) is formed in the interlayer dielectric (304) on the first wiring layer (102) by photolithography and dry etching (FIG. 3C).

Then, aluminum oxide (113) is deposited on the dielectric (306) between wiring layers and the opening (305) by ALD. ALD is carried out 25 cycles with trimethyl aluminum and ozone to obtain a 2 nm-thick thin film (FIG. 3D). The substrate temperature for this process can be selected from a range from 300° C. to 400° C. Niobium oxide is then deposited to a thickness of 5 nm by thermal CVD using pentaethoxy niobium and oxygen. The substrate temperature for this process can be selected from a range from 300° C. to 400° C. Subsequently, a crystallized niobium oxide thin film (114) is obtained by heating at 450° C. in an oxidative atmosphere (FIG. 3E). The annealing of this niobium oxide after CVD will be referred to as “crystallization annealing” hereinafter. After a tungsten film is deposited in the opening by thermal CVD, the tungsten thin film in an area other than the opening is removed by the known etch-back step to obtain tungsten (112) buried in the opening (FIG. 3F). A barrier metal thin film (307), wiring metal thin film (308) and barrier metal thin film (309) are formed again sequentially as a second wiring layer (FIG. 3G). This second wiring layer is processed into wiring similarly by photolithography and dry etching to obtain the structure of FIG. 1.

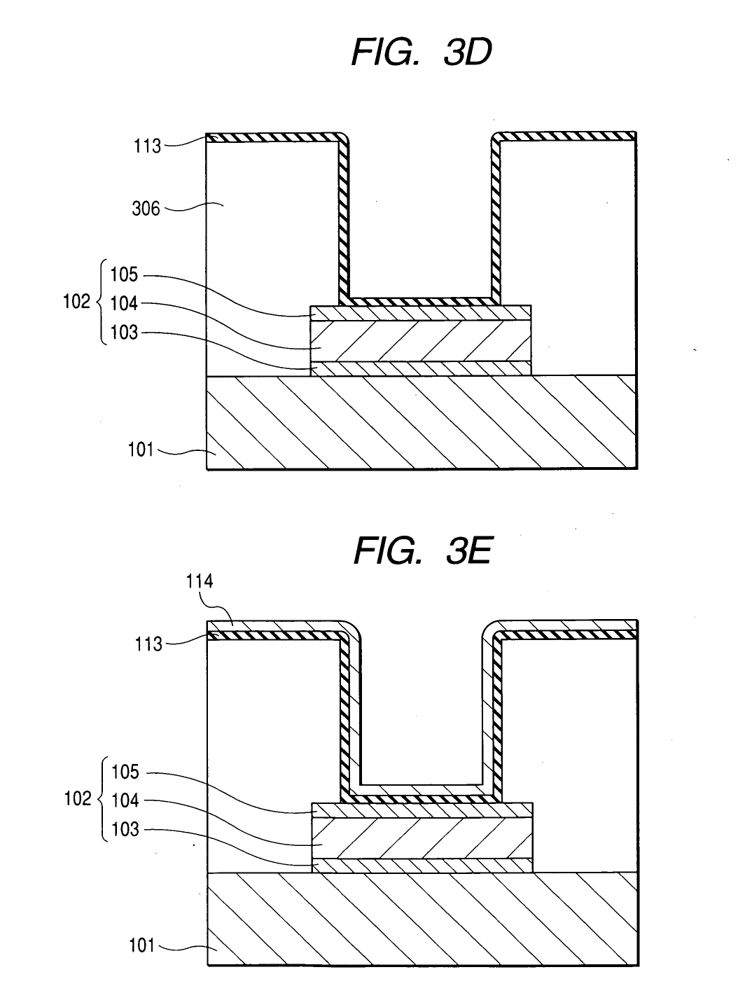

The characteristic properties of the on-chip capacitor manufactured in this embodiment are shown hereinbelow. FIG. 4 shows variations in effective film thickness (teff) by changing the thickness of the niobium oxide film deposited by CVD on the 2 nm-thick aluminum oxide film formed by ALD. The effective thickness is the thickness of an equivalent SiO₂ film which provides the same capacitance. When the dielectric constant of the deposited niobium oxide was calculated from the change rate of the effective thickness based on the thickness of the niobium oxide film, it was 24 without crystallization annealing (represented by “as-depo” in FIG. 4), 428₁-428_{N} 32 when crystallization annealing was carried out at 400° C., 428₁-428_{N} and 51 when crystallization annealing was carried out at 450° C. That is, this shows that niobium oxide can be crystallized surely by crystallization annealing at 450° C.

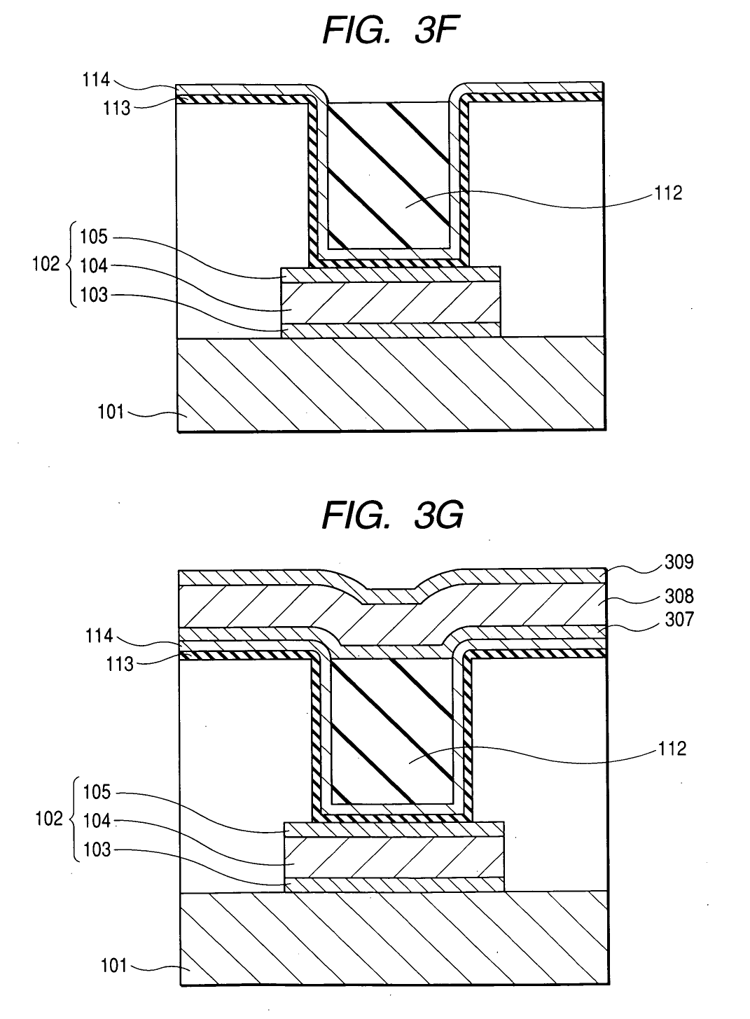

FIG. 5 shows the comparison of the leakage current waveform when crystallization annealing is carried out at 450° C. The vertical axis shows leakage current density and the horizontal axis shows application voltage. The thickness of the aluminum oxide film is 2 nm. When only the aluminum oxide film is existent (represented by “AlO only” in FIG. 5) or when only the niobium oxide film is existent (represented by “NbO only” in FIG. 5), the leakage current is extremely large and insulation properties disappear. This is because when only the aluminum oxide film is existent, as the film thickness is small at 2 nm, the direct tunnel current between electrodes is large, and when only the niobium oxide film is existent, the energy barrier of junction between the electrode and the niobium oxide becomes small. When a 5 nm-thick niobium oxide film is formed on the aluminum oxide film, the direct tunnel current sharply drops due to an increase in film thickness and the energy barrier becomes large due to aluminum oxide existent on the surface of the electrode. It has been found that the leakage current is greatly suppressed by the combined function of these two films. When the thickness of the deposited niobium oxide film is increased (10 nm), the current density is further reduced. Not shown in FIG. 5, as a result of detailed studies made on the thickness of the niobium oxide film and the thickness of the aluminum oxide film, the direct tunnel current sharply rises when the total thickness of the two films becomes smaller than 5 to 6 nm. Thereby, it has been found that the total thickness of the two films must be at least 5 nm, preferably 6 nm or more.

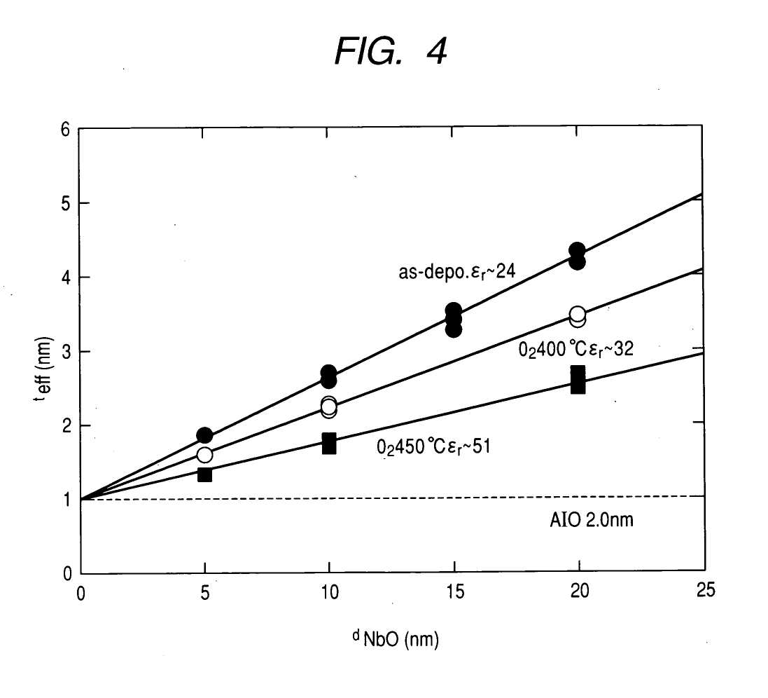

FIG. 6 shows the influence upon leakage current of the crystallization annealing temperature. In order to investigate dependence upon annealing temperature, an experimental sample manufactured by forming a capacitor comprising barrier metal layers (103, 105) without forming a metal wiring layer (104) in FIG. 1 to eliminate deterioration by the use of the metal wiring layer. The thickness of the aluminum oxide layer was 2 nm and the thickness of the niobium oxide layer was 6 nm. When crystallization annealing was not carried out (expressed as “as deposited” in FIG. 6), the leakage current was smaller at 1.2 V or more but larger at a voltage lower than 1.2 V as compared with samples which crystallized at 450° C. Looking at the graph in more detail, the leakage current is reduced by crystallization in an area where the leakage current increases gradually (about 1 V or lower in the case of crystallization at 450° C., 1.5 V or lower without crystallization) whereas the leakage current is increased by crystallization on a high field side where the leakage current sharply rises. A reduction in leakage current on a low field area by crystallization is considered that the current flowed through a defect in the film drops. In fact, the dielectric loss at 0 V was about 2% when crystallization annealing was not carried out and less than 1% after crystallization annealing was carried out 450° C. An increase in leakage current in a high field portion by crystallization is considered to be due to a rise in the dielectric constant of niobium oxide by crystallization. The effective film thickness was reduced from 2 nm to about 1.6 nm by the crystallization of niobium oxide (when the thickness of the niobium oxide film is 6 nm). Even when the same voltage is applied, the electric field applied to aluminum oxide increases (more specifically, increases in inverse proportion to the effective film thickness). Therefore, the leakage current increases on the high field side in FIG. 6, which does not show that the quality of the film is deteriorated by crystallization. It rather shows that the quality of the film improves as the leakage is reduced at a low electric field.

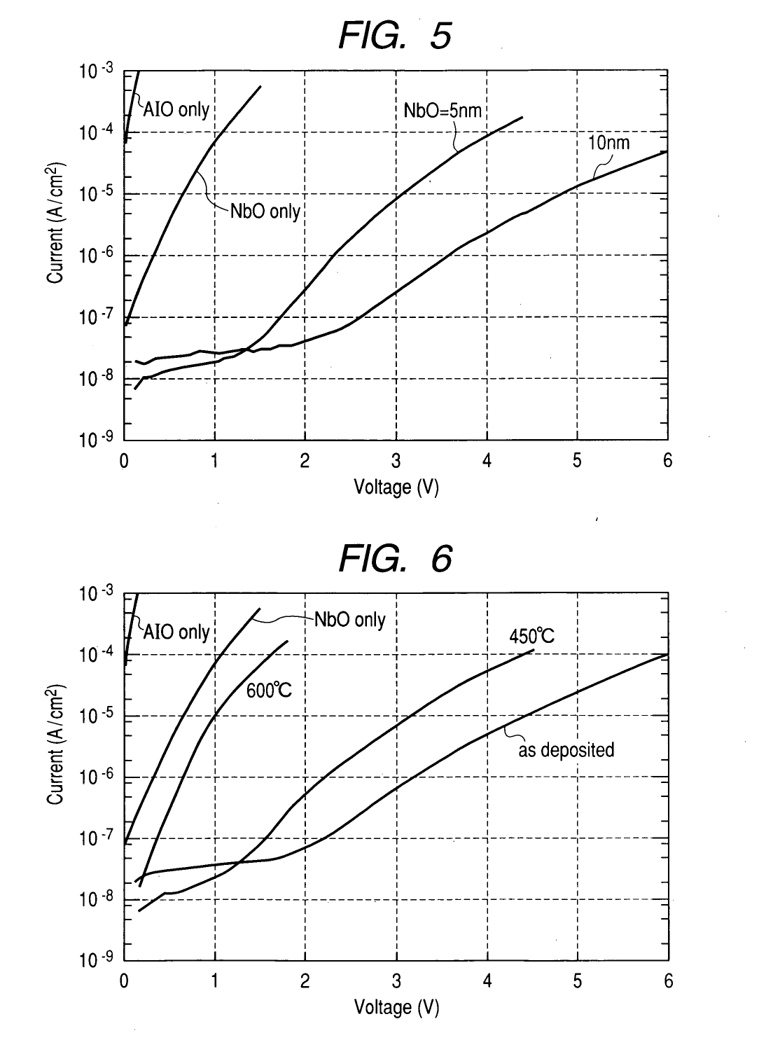

FIG. 7 shows the study results of the temperature characteristics of capacitance. FIG. 7 shows the temperature coefficients (expressed as TCC in FIG. 7) and dielectric constants (expressed as Dielectric Constant in FIG. 7) of aluminum oxide and niobium oxide used in the present invention on the vertical and horizontal axes, respectively. In FIG. 7, the reason that TCC has a certain range is a phenomenon that the temperature coefficient increases as the dielectric loss grows, which has been discovered in studies conducted by the inventors of the present invention. That is, it has been found that when the dielectric constant is 20, the temperature coefficient is between −100 ppm/° C. and 0 without a loss and when the loss is 1%, the temperature coefficient is around 300 ppm/° C. A certain range of temperature coefficient is observed from the behavior of the dielectric loss. The temperature coefficient of aluminum oxide (expressed as AlO in FIG. 7) was a value ranging from +200 ppm/° C. to +300 ppm/° C. and the dielectric constant thereof was almost 8 when suitable ALD conditions were selected. When the crystallization annealing of niobium oxide was not carried out, the temperature coefficient of niobium oxide was a value larger than +400 ppm/° C. and the dielectric constant thereof (expressed as a-NbO in FIG. 7) was 24 as shown in FIG. 7. Meanwhile when crystallization annealing was carried out at 450° C., the temperature coefficient was typically −500 ppm/° C. and may become −700 ppm/° C. according to annealing conditions. The dielectric constant was 51 as shown in FIG. 7 (expressed as c-NbO in FIG. 7).

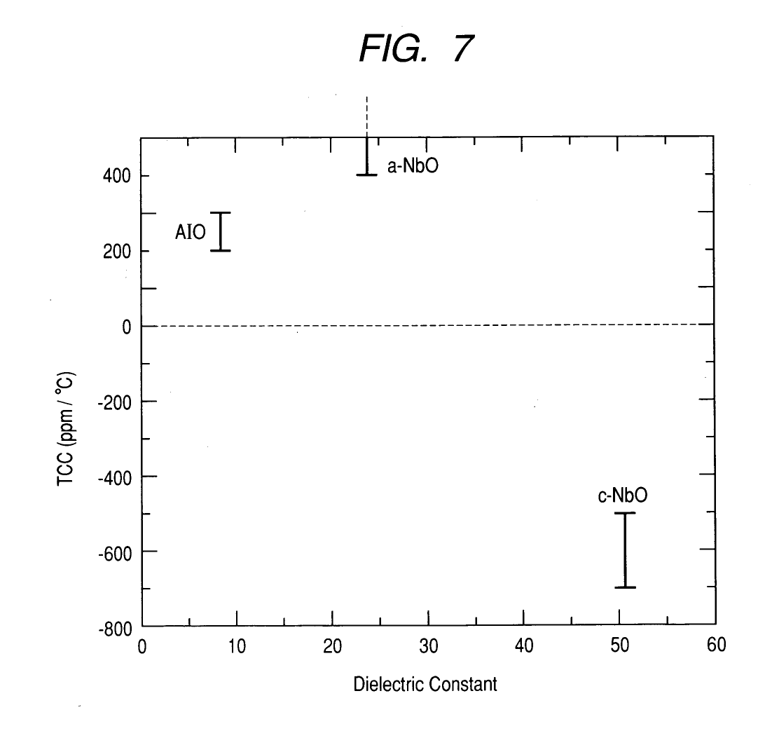

FIG. 8 shows the temperature characteristics of a capacitor having the structure of FIG. 1 that this aluminum oxide layer and the crystallization annealed niobium oxide layer are laminated together. The horizontal axis shows the film thickness ratio of the aluminum oxide layer to the total thickness of the two layers. It can be understood that when the temperature coefficient is within ±100 ppm/° C., the film thickness rate of aluminum oxide is 20 to 50% (the film thickness ratio of aluminum oxide to niobium oxide is between 0.2 and 1) and that the film thickness rate of almost 0 is obtained when the film thickness ratio of aluminum oxide to niobium oxide is 0.4 to 0.7. That is, the film thickness of aluminum oxide required to compensate for the large negative temperature coefficient of niobium oxide is 0.2 to 1, preferably 0.4 to 0.7 based on the film thickness of niobium oxide.

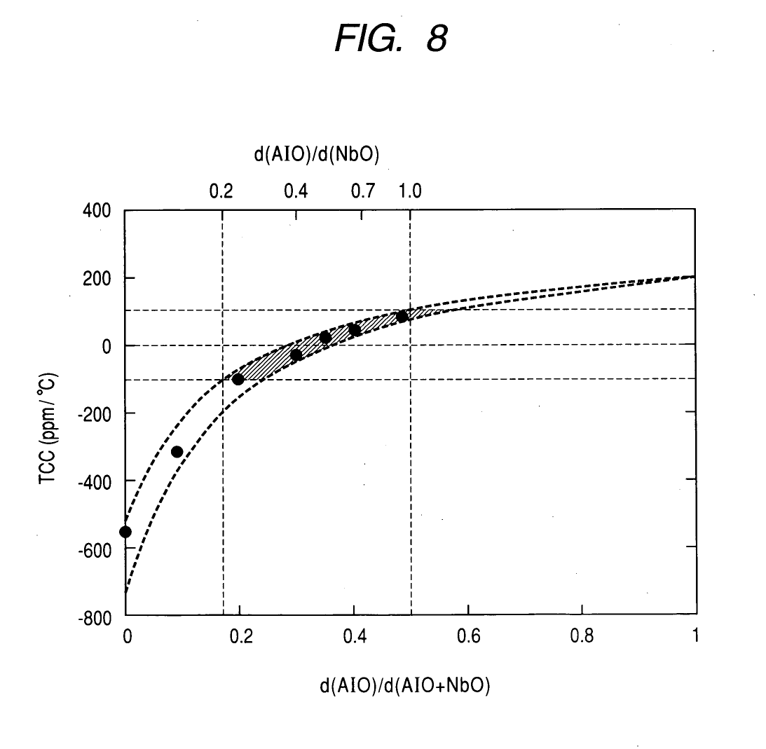

Thereafter, the evaluation result of the reliability of this capacitor is shown. FIG. 9 shows the relationship between dielectric loss and time to failure obtained by a constant voltage stress acceleration test. The multi-layer capacitor of the present invention has an average dielectric loss of about 0.5% which is shown by black circles in the figure. When it is compared with capacitors manufactured by making crystallization incomplete by reducing the crystallization annealing temperature to increase the dielectric loss intentionally (average dielectric loss of 0.58% (white circles), 0.65% (squares)), the average time to failure is longer and variations in time to failure are smaller. Therefore, the reliability of the capacitor is improved by reducing the dielectric loss. It is understood from these results that the dielectric loss must be reduced to about 0.5% or less.

This suggests an extremely important relationship between temperature coefficient and reliability. That is, to improve reliability, the dielectric loss must be made very small. However, when a dielectric having a much higher dielectric constant than conventional silicon nitride, for example, a dielectric having a dielectric constant higher than 20 is used as described above, the temperature coefficient in this state becomes a very large negative value. In short, it has been found that when a dielectric material having a much higher dielectric constant than the prior art is used alone, the required temperature coefficient and reliability cannot be obtained at the same time and that the temperature characteristics must be corrected by using a laminate structure.

FIG. 1 and FIGS. 3A to 3G show that niobium oxide is deposited by thermal CVD using pentaethoxy niobium and oxygen. To deposit niobium oxide at a lower temperature or at a higher throughput, CVD making use of plasma excitation may be employed. However, as the step coverage deteriorates in this case, the film thickness of niobium oxide must be increased while the film thickness ratio of aluminum oxide to niobium oxide of the present invention is maintained. When a low-cost process is necessary, though all the layers including aluminum oxide and niobium oxide layers can be formed by sputtering, the step coverage further deteriorates, whereby the film thickness of niobium oxide must be further increased while the film thickness ratio is maintained. When the step coverage is important, niobium oxide must be deposited by ALD as well.

The upper barrier metal layer (105) of the first wiring layer (102) is directly exposed to the atmosphere when the capacitor dielectric is formed as shown in FIG. 3C and FIG. 3D, the selection of a material is important. Although titanium nitride is used in FIG. 1, another material can be selected from tantalum, tungsten, molybdenum and nitrides thereof. Similarly, the buried metal (112) as the top electrode can be selected from titanium, tantalum, tungsten, molybdenum and nitrides thereof.

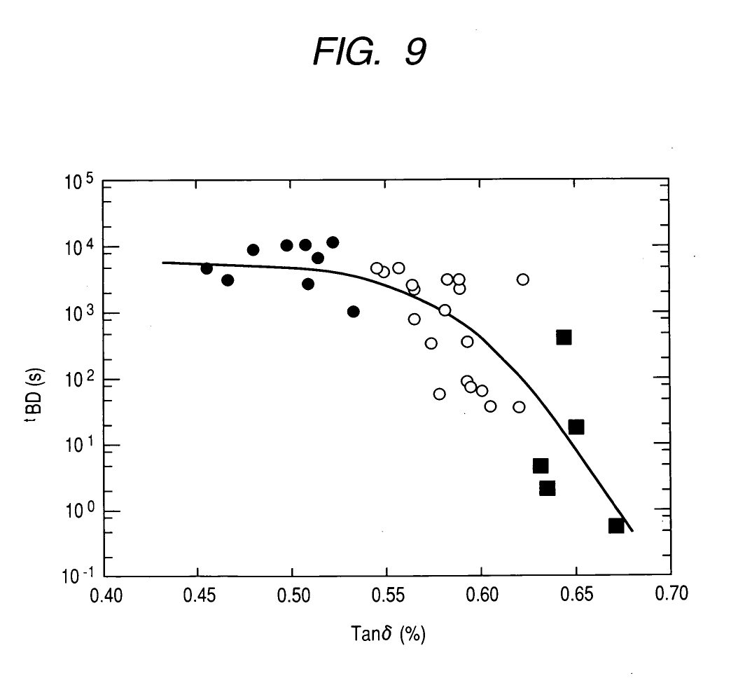

FIG. 1 shows an example where there is a level difference equal to or larger than the film thickness of the wiring layer between the first wiring layer (102) and the second wiring layer (106). The present invention can be applied to a case where this level difference is small. FIG. 10 shows a preferred example where this level difference is small. An insulating film (601) essentially composed of SiO₂ is formed to cover the top face and side faces of the first wiring layer (102) and an opening from which part of the upper barrier metal layer (105) of the first wiring layer is exposed is formed in the top face. After an aluminum oxide layer (602) and a niobium oxide layer (603) are formed and crystallized, the second wiring layer (106) is formed. The characteristic features of this structure are that there is no buried electrode which is required in FIG. 1 and that the second wring layer is directly formed. This is also a preferred embodiment of the present invention in which a high dielectric film is interposed between the first and second wiring layers.

### Embodiment 2

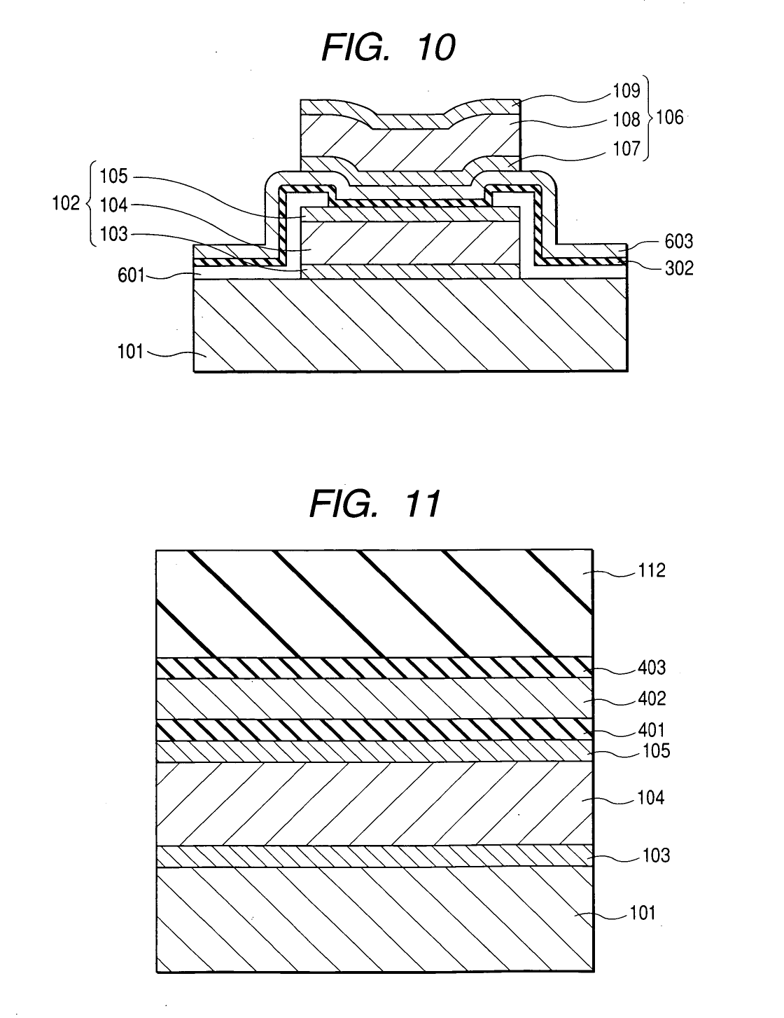

A lamination method according to another preferred embodiment of the present invention is disclosed next. Since the principle of the present invention is to carry out temperature correction with the film thickness ratio of aluminum oxide to niobium oxide, it is of no essential significance that aluminum oxide and niobium oxide disclosed in FIG. 1 and FIGS. 3A to 3G are deposited in the mentioned order. Niobium oxide may be deposited first. Further, FIG. 11 shows only the electrode/dielectric laminated structure of the capacitor shown in FIG. 1 which has a three-layer structure consisting of an aluminum oxide layer (401), niobium oxide layer (402) and aluminum oxide layer (403). Also in this case, the present invention can be carried out by setting the ratio of the total thickness of the upper and lower aluminum oxide layers (401, 403) to the thickness of the niobium oxide layer (402) to 0.2 to 1, preferably 0.4 to 0.7.

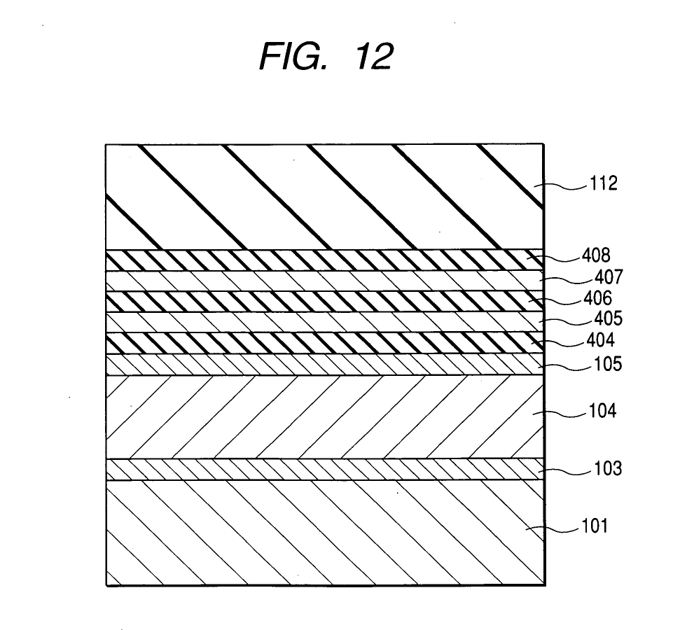

When a higher application voltage is used, the aluminum oxide/niobium oxide laminated structure is preferably used a plurality of times as shown in FIG. 12. This is because the thickness of a crystallized film must be about 10 nm or less to crystallize niobium oxide into a high-dielectric phase and to obtain a small dielectric loss. Therefore, to manufacture the structure of FIG. 12, the step of carrying out crystallization annealing each time niobium oxide is deposited is preferably employed and not the step of forming a laminated structure and carrying out crystallization annealing in the end. FIG. 12 shows that two niobium oxide layers are formed. Although two niobium oxide layers are formed in FIG. 12, it is needless to say that three or more niobium oxide layers may be formed. In FIG. 12, the aluminum oxide layer (408) is in contact with the top electrode (112). A case where the niobium oxide layer is in contact with the top electrode is one of the preferred embodiments of the present invention. The present invention can be carried out by setting the ratio of the total thickness of aluminum oxide layers to the total thickness of niobium oxide layers to 0.2 to 1, preferably 0.4 to 0.7 even in these structures having multiple laminates.

### Embodiment 3

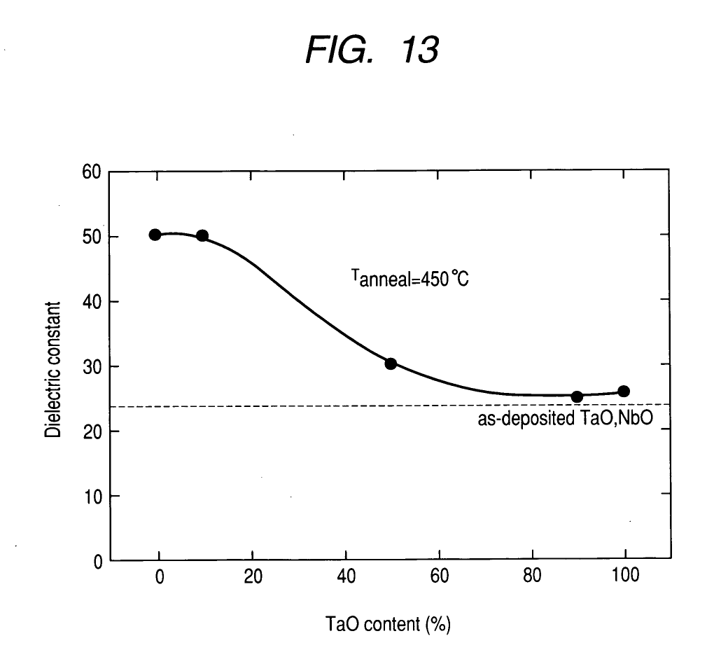

Other preferred materials of the niobium oxide layer in the present invention are disclosed next. Although niobium oxide is a dielectric which can be crystallized at 300 to 400° C. specifically, out of simple oxides showing high insulating properties, when its insulation resistance is compared with those of other similar simple oxides, it is slightly lower. To improve this, tantalum oxide was mixed with niobium oxide. FIG. 13 shows the dependence upon mixing ratio of dielectric constant when the crystallization annealing of a mixed film deposited on the 2 nm-thick aluminum oxide film was carried out at 450° C. When the mixing ratio of tantalum oxide was 10% or less, the same dielectric constant as pure niobium oxide was obtained and the desired effect of increasing insulation resistance could be obtained. That is, the niobium oxide layer of the present invention can be mixed with tantalum oxide in a mixing ratio of 10% or less. Also in this case, the present invention can be carried out by setting the ratio of the thickness of the aluminum oxide layer to the thickness of the niobium oxide-tantalum oxide mixed layer to 0.2 to 1, preferably 0.4 to 0.7.

### Embodiment 4

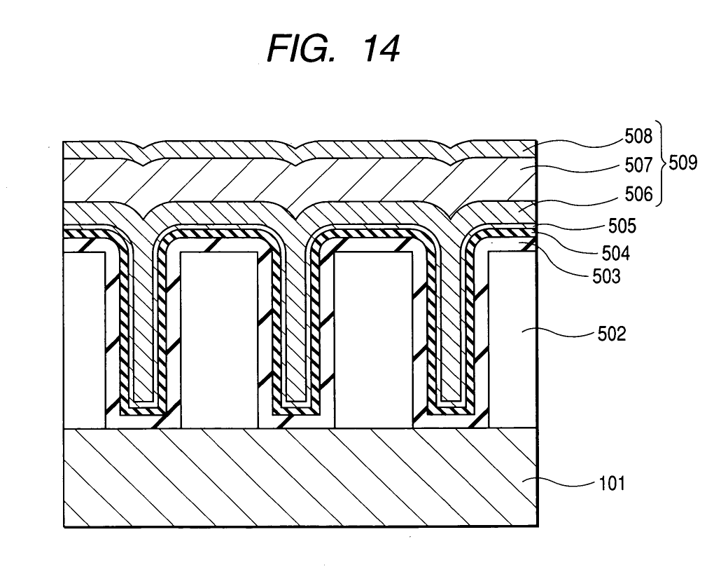

An embodiment which is effective in further reducing the size of the capacitor of the present invention is shown next. FIG. 14 is a sectional view of the capacitor of this embodiment. An interlayer dielectric (502) essentially composed of SiO₂ and having a plurality of openings is existent on a semiconductor substrate (101) having an active device formed thereon, and a bottom electrode (503) is formed on the entire surfaces (bottom and side walls) of the inner walls of the openings and the top of the interlayer dielectric between the openings by CVD. Thereafter, an aluminum oxide film (504) is deposited by ALD and a niobium oxide film (505) is deposited by ALD and annealed to be crystallized. The lower barrier metal layer (506) of the second wiring layer (509) also serves as the top electrode of the capacitor in this embodiment and is buried in the openings to interconnect adjacent openings. As a matter of course, the lower barrier metal and the top electrode for the second wiring layer may be formed separately according to a preferred embodiment of the present invention. ALD for forming the niobium oxide layer can be carried out by using pentaethoxy niobium or other alkylamido compound and water or ozone as an oxidizing agent as raw materials.

### Embodiment 5

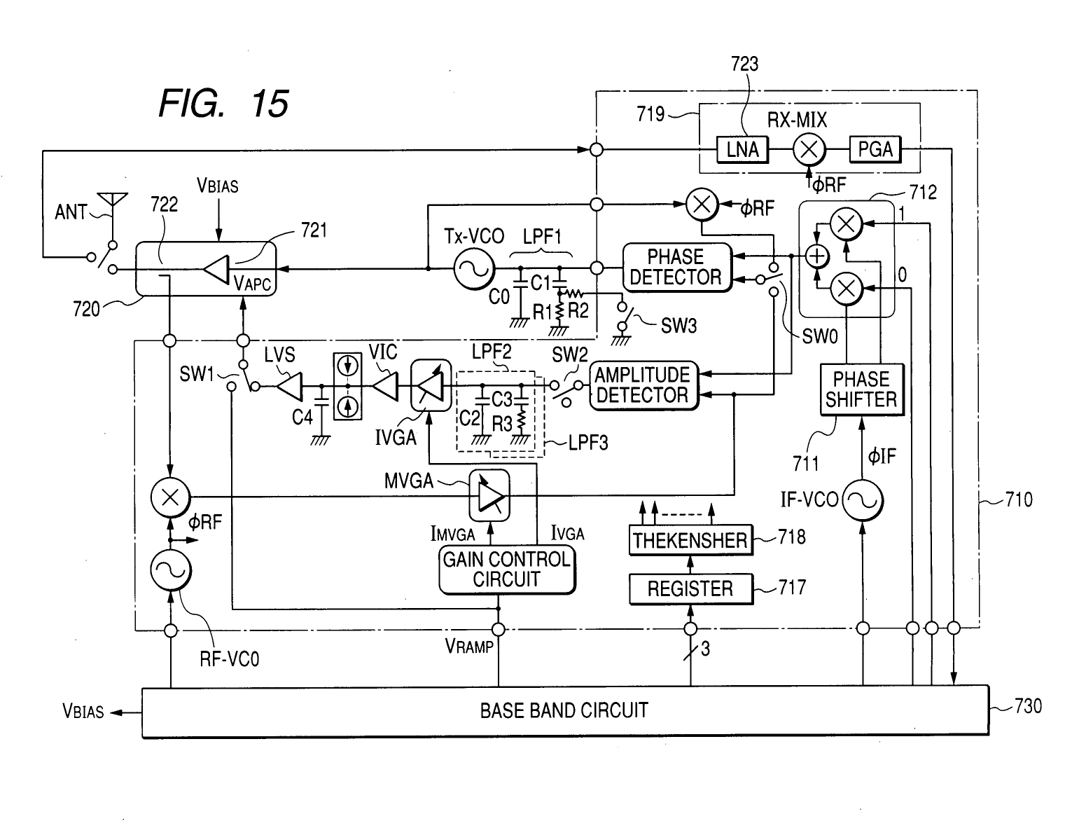

FIG. 15 shows an example when the capacitor of the present invention is used in a GSM radio communication apparatus.

In FIG. 15, reference numeral 710 denotes a high-frequency IC in the GSM system, 720 a power module including a high frequency power amplifying circuit 721 for transmitting a signal by driving an antenna ANT, 730 a base band circuit for producing an l/Q signal based on transmitted data (base band signal), TxVCQ a transmission oscillator for producing a phase-modulated transmission signal (carrier wave), and LPF1 a loop filter for limiting the band of a phase control loop.

A low noise amplifier (LNA) 723, a mixer (Rx-MIX) for down converting a received signal into a base band signal directly and a receiving circuit 719 composed of a high-gain programmable gain amplifier (PGA) are formed on the chip of the high-frequency IC 710.

An input matching capacitor having high accuracy is required for the low noise amplifier (LNA) installed in the first stage of the above receiving circuit.

The effect of improving the performance of a circuit can be obtained by using the capacitor of the present invention as the above high-precision input matching capacitor.

In the prior art, most of these passive devices are external to a printed circuit board. By mounting these passive devices on a semiconductor chip, the inductance of wiring from the chip to the capacitor can be reduced, thereby making it possible to increase the operation speed of an integrated circuit and cut costs by reducing the number of parts.

What is claimed is:

1. An integrated semiconductor device comprising an analog integrated circuit or mixed signal integrated circuit having a capacitor, wherein the dielectric film of the capacitor is a laminated film consisting of a first dielectric film essentially composed of aluminum oxide and a second dielectric film essentially composed of crystallized niobium oxide.

2. The integrated semiconductor device according to claim 1, wherein the physical thickness ratio of the first dielectric film to the second dielectric film is 0.2 to 1.

3. The integrated semiconductor device according to claim 1, wherein the total thickness of the first dielectric film and the second dielectric film is 6 nm or more.

4. An integrated semiconductor device comprising a capacitor having a temperature coefficient of capacitance of +100 ppm/° C. or less, wherein
the dielectric film of the capacitor is a laminated film consisting of a first dielectric film essentially composed of aluminum oxide and a second dielectric film essentially composed of crystallized niobium oxide.

5. The integrated semiconductor device according to claim 4, wherein the physical thickness ratio of the first dielectric film to the second dielectric film is 0.2 to 1.

6. The integrated semiconductor device according to claim 4, wherein the total thickness of the first dielectric film and the second dielectric film is 6 nm or more.

7. The integrated semiconductor device according to claim 4, wherein the dielectric loss of the laminated film consisting of the first dielectric film and the second dielectric film is 0.5% or less.

8. The integrated semiconductor device according to claim 4, wherein the dielectric film of the capacitor consists of a plurality of laminated films, each consisting of the first dielectric film and the second dielectric film.

9. The integrated semiconductor device according to claim 8, wherein the thickness of the niobium oxide film is 10 nm or less.

10. The integrated semiconductor device according to claim 4, wherein the second dielectric film contains crystallized tantalum oxide.

11. A method of manufacturing an integrated semiconductor device comprising an analog integrated circuit or mixed signal integrated circuit having a MIM capacitor, wherein the step of forming the dielectric film of the capacitor includes the step of forming a laminated film consisting of an aluminum oxide film and a niobium oxide film on the bottom electrode essentially composed of a metal of the capacitor formed on a substrate and the step of thermally annealing the substrate having the laminated film at 450° C. or lower in an oxidative atmosphere.

12. The method of manufacturing an integrated semiconductor device according to claim 11, wherein the aluminum oxide film is deposited by atomic layer deposition at a temperature of 400° C. or lower.

13. The method of manufacturing an integrated semiconductor device according to claim 11, wherein the aluminum oxide film is deposited by sputtering.

14. The method of manufacturing an integrated semiconductor device according to claim 11, wherein the niobium oxide film is deposited by thermal CVD at a temperature of 400° C. or lower.

15. The method of manufacturing an integrated semiconductor device according to claim 11, wherein the niobium oxide film is deposited by plasma CVD.

16. The method of manufacturing an integrated semiconductor device according to claim 11, wherein the niobium oxide film is deposited by sputtering.

17. The method of manufacturing an integrated semiconductor device according to claim 11, wherein the dielectric loss of the laminated film consisting of the first dielectric film and the second dielectric film is 0.5% or less.

18. The method of manufacturing an integrated semiconductor device according to claim 11, wherein a plurality of laminated films, each consisting of an aluminum oxide film and a niobium oxide film, are formed.

19. The method of manufacturing an integrated semiconductor device according to claim 18, wherein the thickness of the niobium film is 10 nm or less.

20. The method of manufacturing an integrated semiconductor device according to claim 11, wherein the niobium oxide film contains crystallized tantalum oxide.
